(19) United States
(12) Patent Application Publication
(10) Pub. No.: US 2005/0212093 A1
(43) Pub. Date: Sep. 29, 2005

(54) Semiconductor device and apparatus for fabricating the same

(75) Inventor: Yoshinori Takamori, Kyoto (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/082,895

(22) Filed: Mar. 18, 2005

(30) Foreign Application Priority Data
Mar. 26, 2004 (JP) 2004-091463

(51) Int. Cl. H01L 23/58; C23C 16/00

(52) U.S. Cl. 257/632; 118/715

(57) ABSTRACT

A semiconductor device includes a plurality of elements formed on a semiconductor substrate and an interlayer dielectric formed on the semiconductor substrate to fill spaces between adjacent ones of the plurality of elements. The concentration of an impurity in the interlayer dielectric is nonuniform in a direction along the thickness of the interlayer dielectric.

### CROSS-REFERENCE TO RELATED APPLICATIONS

The disclosure of Japanese Patent Application No. 2004-091463 including specification, drawing and claims is incorporated herein by reference in its entirety.

### BACKGROUND OF THE INVENTION

1. Field of the Invention

The present invention relates to a semiconductor device and an apparatus for fabricating the same, and more particularly relates to a semiconductor device comprising a dielectric which is formed between elements, such as transistors, resistances and capacitances, and a metal interconnect formed above the elements by Chemical Vapor Deposition (CVD) and contains impurities, such as boron and phosphorus, and an apparatus for fabricating the same.

2. Description of Related Art

In semiconductor devices, such as microprocessors and memories, the dimensions of their individual elements are being miniaturized with a higher degree of integration. As a result, the interelement distances are becoming smaller. Typically, such semiconductor devices have a dielectric formed between the regions occupied by transistors or other elements formed on a semiconductor substrate and an interconnect layer formed above the above regions. In particular, a film formed between the transistors and the interconnect layer is referred to as a Pre Metal Dielectric (PMD). The PMD is a dielectric generally containing impurities, such as boron and phosphorus, and functions as a film which fills spaces between elements formed on a semiconductor substrate.

The PMDs, however, have caused poor filling of interelement spaces due to the fact that the dimensions of each of the interelement spaces are being miniaturized with the increasing miniaturization of elements. In order to make electrical contact between active regions (for example, source/drain regions) formed in the semiconductor substrate and an interconnect, through holes must be formed in the PMD. However, if the interelement spaces are insufficiently filled with the PMD, this adversely affects etching for forming through holes. For example, etching is stopped midway before through holes reach the semiconductor substrate.

In order to eliminate poor filling of interelement spaces, various methods for fabricating a semiconductor device have conventionally been suggested in which the interelement space filling property of the PMD is improved by enhancing the fluidity of the PMD (for example, Japanese Unexamined Patent Publication No. 2000-150637). For example, a method has been suggested in which the fluidity of the PMD is enhanced by increasing the content of impurities, such as boron or phosphorus, in the PMD. Furthermore, a method has been suggested in which the fluidity of the PMD is enhanced by employing, as conditions for forming the PMD, for example, a pressure condition of 5.32×10⁴ Pa (400 Torr) or more or a wafer temperature condition of 500° C. or more. In addition, a method has been suggested in which the fluidity of the PMD is enhanced by subjecting the PMD to annealing at a temperature of 850° C. or more in an anealing process step subsequent to the formation of the PMD. The interelement space filling property is improved by carrying out these methods for fabricating a semiconductor device separately. Alternatively, if these methods for fabricating a semiconductor device are used at the same time, the interelement space filling property will still further be improved.

By the way, since the above-mentioned conventional methods for fabricating a semiconductor device improve the interelement space filling property, conventionally used semiconductor device fabricating apparatuses can subsequently be used. However, constraints on a semiconductor device fabricating process may prevent the above-mentioned conventional methods from being employed. For example, an increase in the temperature at which the PMD is formed and an increase in the temperature at which annealing is carried out affect the impurity concentration in an active region of a transistor, leading to the deteriorated property of the semiconductor device. Furthermore, if the impurity concentration in the PMD is increased, a problem may arise that impurities will be deposited. Therefore, the concentration of impurities cannot significantly be increased.

Although the formation of the PMD under the above-mentioned high pressure condition does not affect the property of the semiconductor device, it has a trade-off relationship with the film formation rate, leading to the reduced throughput. This decreases productivity, resulting in the increased CoO (Cost of Ownership).

Furthermore, for a 130-nm-or-more technology node having an interelement distance of 100 nm or less, the conventionally used semiconductor device fabricating apparatuses cannot subsequently be used even with the use of the above-described conventional methods for fabricating a semiconductor device.

As described above, if any of conventional semiconductor device fabricating methods is used to form a PMD containing impurities, such as boron and phosphorus, this can improve the interelement space filling property while causing adverse effects, for example, deterioration in electric characteristics, such as transistor characteristics, or reduction in the productivity of the semiconductor device fabricating apparatuses. Therefore, the conventional semiconductor device fabricating methods and apparatuses do not provide satisfactory performance, such as transistor characteristics or the productivity of the semiconductor device fabricating apparatuses.

### SUMMARY OF THE INVENTION

In view of the above, an object of the present invention is to provide a semiconductor device comprising an interlayer dielectric with an excellent interelement space filling property and a semiconductor device fabricating apparatus for forming the interlayer dielectric with excellent interelement space filling property. The elements are formed on a semiconductor substrate.

In order to achieve the above object, the present inventors made various studies. Generally, the following has been known: when a dielectric containing impurities, such as boron or phosphorus, is used as a PMD, the interelement space filling property of the PMD depends on the impurity concentration in the PMD, the wafer temperature during PMD formation, or the chamber pressure during PMD formation; and an increase in the impurity concentration in the PMD, an increase in the wafer temperature during PMD formation, or an increase in the pressure during PMD formation improves the interelement space filling property of the PMD. On the other hand, the present inventors found that the fluidity of the PMD is enhanced during the formation thereof by decreasing the reactivity between a material gas for forming the PMD and the top surface of a semiconductor substrate. More specifically, if the reactivity between the material gas and the top surface of the semiconductor substrate is reduced, i.e., a large amount of unreacted material gases are produced and many unreacted material gases are contained in the PMD, the fluidity of the PMD is not lost during the formation thereof. Therefore, an excellent interelement space filling property of the PMD is realized. Furthermore, although annealing is performed in an atmosphere containing nitrogen, oxygen, or a mixed gas of them to further improve the filling property after the formation of the PMD, the present inventors found that an excellent interelement space filling property of the PMD is realized by permitting, also during this annealing, the presence of unreacted material gases in the PMD.

The present invention is made based on the above finding. More specifically, a semiconductor device of one aspect of the present invention includes: a plurality of elements formed on a semiconductor substrate; and an interlayer dielectric formed on the semiconductor substrate to fill spaces between adjacent ones of the plurality of elements, wherein the concentration of an impurity in the interlayer dielectric is nonuniform in a direction along the thickness of the interlayer dielectric.

According to the semiconductor device of the aspect of the present invention, the impurity concentration in the interlayer dielectric is nonuniform in a direction along the thickness of the interlayer dielectric, i.e., the interlayer dielectric has a concentration gradient. Therefore, unreacted material gases are produced during the formation of the interlayer dielectric, resulting in the unreacted material gases contained in the interlayer dielectric. Therefore, the fluidity of the interlayer dielectric itself is not lost during both the formation of the interlayer dielectric and the subsequent annealing. This can provide a semiconductor device comprising an interlayer dielectric having an excellent interelement space filling property. Since the fluidity of the interlayer dielectric is not lost, this allows the interlayer dielectric to have excellent flatness. Therefore, the processing time of Chemical Mechanical Polishing (CMP) for global planarization after the formation of the interlayer dielectric can be shortened, and the productivity of a CMP apparatus can be improved.

In the semiconductor device of the aspect of the present invention, the interlayer dielectric preferably contains at least one of boron and phosphorus as the impurity.

Since the fluidity of the interlayer dielectric itself during the formation of the interlayer dielectric is thus improved, this enhances the interelement space filling property of the interlayer dielectric.

In the semiconductor device of the aspect of the present invention, the impurity concentration in a region of the interlayer dielectric located in the vicinity of the semiconductor substrate is preferably higher than the average impurity concentration in the interlayer dielectric.

With this structure, since the fluidity of the interlayer dielectric itself in the early stages of the formation of the interlayer dielectric is further improved, this can provide a semiconductor device comprising an interlayer dielectric having a more excellent interelement space filling property.

In the semiconductor device of the aspect of the present invention, the impurity concentration in the region of the interlayer dielectric located in the vicinity of the semiconductor substrate is preferably 10% through 20% both inclusive higher than the average impurity concentration in the interlayer dielectric.

With this structure, an interlayer dielectric having an excellent interelement space filling property can be realized with reliability.

A semiconductor device fabricating apparatus of one aspect of the present invention that forms an interlayer dielectric on a semiconductor substrate to fill spaces between a plurality of elements formed on the semiconductor substrate by introducing a plurality of material gases into a chamber, wherein said apparatus includes: flow rate controllers for controlling the flow rates of the plurality of material gases, respectively; and a monitoring mechanism for monitoring the flow rates of the plurality of material gases or an atmosphere in the chamber during the formation of the interlayer dielectric.

According to the semiconductor device fabricating apparatus of the aspect of the present invention, unreacted material gases are produced during the formation of the interlayer dielectric by the flow rate controllers and the monitoring mechanism, thereby allowing the interlayer dielectric to contain the unreacted material gases. Therefore, the fluidity of the interlayer dielectric itself is not lost during both the formation of the interlayer dielectric and the subsequent annealing. This can provide a semiconductor device fabricating apparatus that can fabricate a semiconductor device comprising an interlayer dielectric having an excellent interelement space filling property. Furthermore, the semiconductor device fabricating apparatus of the present invention has a structure in which some of existing semiconductor device fabricating apparatuses can be utilized as they are. Therefore, a semiconductor production line can be taken over without the need for a large additional investment. In addition, since the fluidity of the interlayer dielectric is not lost, this allows the interlayer dielectric to have excellent flatness. Therefore, the processing time of CMP after the formation of the interlayer dielectric can be shortened, and the productivity of a CMP apparatus can be improved. The CMP is intended to reduce the global level difference.

In the apparatus of the aspect of the present invention, the monitoring mechanism for monitoring the atmosphere in the chamber is preferably a residual gas analyzer.

It is preferable that the apparatus of the aspect of the present invention further includes a process stopping mechanism for stopping the formation of the interlayer dielectric when the statuses of the monitored flow rates of the plurality of material gases or the change of the monitored atmosphere in the chamber do not correspond with a desired impurity concentration profile of the interlayer dielectric.

As described above, according to the semiconductor device of the aspect of the present invention, the impurity concentration in the interlayer dielectric is nonuniform in a direction along the thickness of the interlayer dielectric, i.e., the interlayer dielectric has a concentration gradient. Therefore, unreacted material gases are produced during the formation of the interlayer dielectric, resulting in the unreacted material gases contained in the interlayer dielectric. Therefore, the fluidity of the interlayer dielectric itself is not lost during both the formation of the interlayer dielectric and the subsequent annealing. This can provide a semiconductor device comprising an interlayer dielectric having an excellent interelement space filling property. Since the fluidity of the interlayer dielectric is not lost, this allows the interlayer dielectric to have excellent flatness. Therefore, the processing time of Chemical Mechanical Polishing (CMP) after the formation of the interlayer dielectric can be shortened, and the productivity of a CMP apparatus can be improved. The CMP is intended to reduce the global level difference. Furthermore, according to the semiconductor device fabricating apparatus of the present invention, an existing semiconductor device fabricating apparatus can be utilized as it is. Therefore, a semiconductor production line can subsequently be used without the need for a large additional investment.

### BRIEF DESCRIPTION OF THE DRAWINGS

FIG. 1 is a cross-sectional view showing the structure of the principal part of a semiconductor device according to an embodiment of the present invention.

FIG. 2 is a SEM (Scanning Electron Microscope) photograph showing a section of a TEG (Test Element Group) for evaluating the filling property of a PMD according to an embodiment of the present invention.

FIG. 3 is a SEM photograph showing a section of a TEG for evaluating the filling property of a known PMD, for comparison with the embodiment of the present invention.

FIG. 4 is a graph showing the SIMS (Secondary Ion Mass Spectroscopy) evaluation results of the concentration profiles of boron and phosphorus contained in the PMD during the formation of the PMD according to the embodiment of the present invention.

FIG. 5 is a graph showing the SIMS evaluation results of the concentration profiles of boron and phosphorus contained in the known PMD, for comparison with the embodiment of the present invention.

FIG. 6 is a schematic diagram showing the structure of a semiconductor device fabricating apparatus according to the embodiment of the present invention.

FIG. 7 is a graph showing the relationship between the time and the gas flow rate on conditions under which the PMD is formed according to the embodiment of the present invention.

### DETAILED DESCRIPTION OF THE INVENTION

A semiconductor device according to an embodiment of the present invention and an apparatus for fabricating the same will be described hereinafter with reference to the drawings.

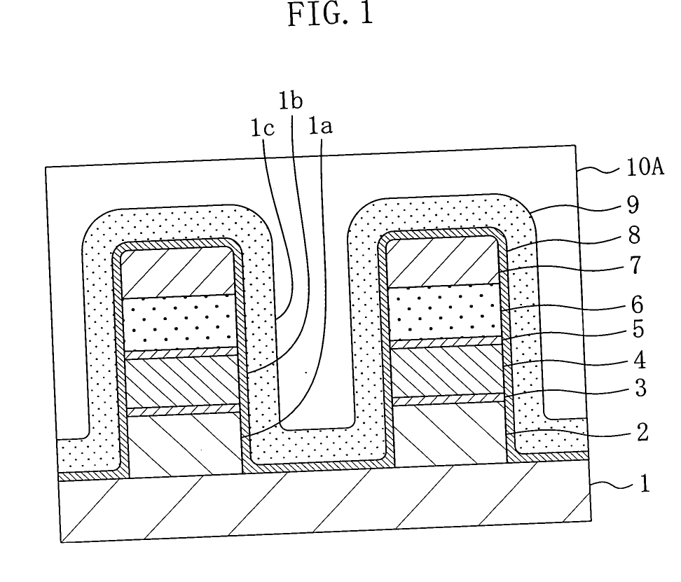

First, the semiconductor device according to the embodiment of the present invention will be described with reference to FIGS. 1 through 5.

FIG. 1 is a cross-sectional view showing the structure of the principal part of the semiconductor device according to the embodiment of the present invention.

As shown in FIG. 1, each of multilayer gate electrodes is formed on an element formation region of a semiconductor substrate 1 made of silicon by stacking a polysilicon film (electrode) 2, a titanium nitride (TiN) film 3, a tungsten (W) film 4, a titanium nitride (TiN) film 5, a silicon nitride (SiN) film 6, and a SiON film 7 in bottom-to-top order. Each of grooves 1a exists between adjacent ones of the multilayer gate electrodes. An anti-oxidation film 8 with grooves 1b is formed on the semiconductor substrate 1 and along the sidewalls and bottoms of the grooves 1a and the top surfaces of the multilayer gate electrodes. A silicon nitride film 9 with grooves 1c is formed, as a spacer film, on the anti-oxidation film 8 and along the sidewalls and bottoms of the grooves 1c. A PMD 10A made of a BPSG (Boron-Phosphorus Silicate Glass) film is formed, as an interlayer dielectric, on the silicon nitride film 9 so that the grooves 1c are filled. Although not shown, a metal interconnect layer is formed on the PMD 10A.

The semiconductor device according to the embodiment of the present invention is distinctive in that the property for the above-described PMD 10A to fill spaces between adjacent ones of the multilayer gate electrodes is excellent. The PMD 10A according to the embodiment of the present invention will be specifically described hereinafter.

First, in order to evaluate the filling property of the PMD 10A according to the embodiment of the present invention, the PMD 10A was evaluated using a TEG for evaluating the filling property. For comparison with the filling property of the PMD 10A according to the embodiment of the present invention, a known PMD 10B (see FIG. 3) was also evaluated using a TEG for evaluating the filling property.

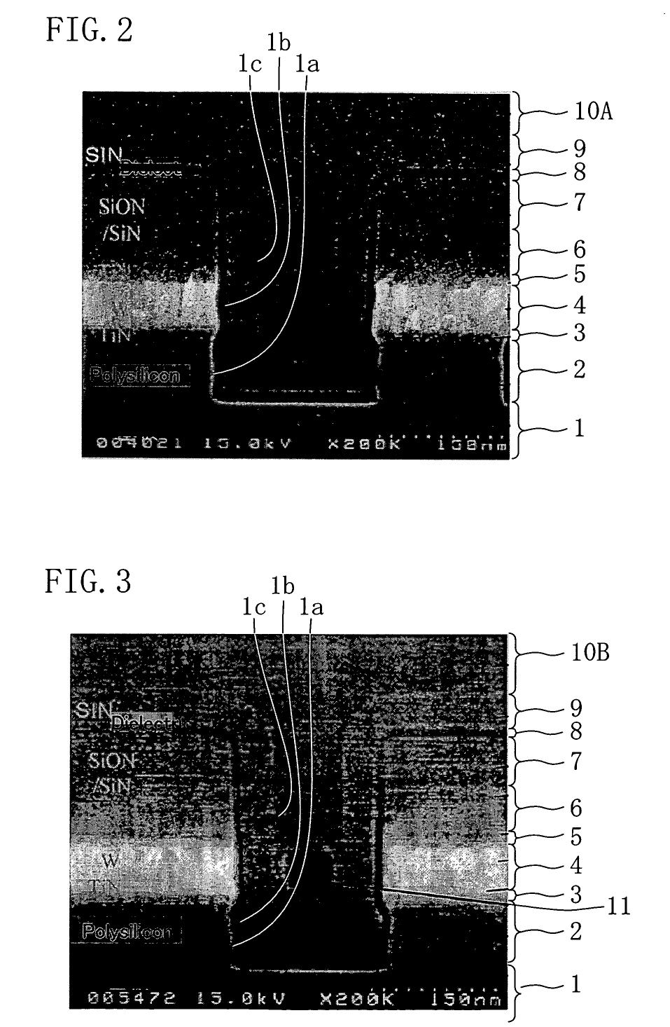

FIG. 2 is a SEM photograph showing a section of the TEG for evaluating the filling property of the PMD 10A shown in FIG. 1. To be specific, it is a SEM photograph showing a section of the TEG for evaluation immediately after the formation of the PMD 10A has finished. This TEG for evaluation is formed to resemble a gate structure of a transistor. This structure is a polymetal gate structure. FIG. 3 is a SEM photograph showing a section of a TEG for evaluating the filling property of the known PMD 10B. FIGS. 3 and 2 are identical with each other except that the PMD 10A according to the embodiment of the present invention is different from the known PMD 10B. Therefore, the same reference numerals are given to the identical components, and a description thereof is not repeated.

The TEG for evaluating the filling property of the PMD film 10A shown in FIG. 2 has the following structure: each of multilayer gate electrodes is formed on an element formation region of a semiconductor substrate 1 made of silicon by stacking a 70-nm-thick polysilicon film (electrode) 2, a 15-nm-thick titanium nitride (TiN) film 3, a 100-nm-thick tungsten (W) film 4, a 15-nm-thick titanium nitride (TiN) film 5, a 100-nm-thick silicon nitride (SiN) film 6, and a 15-nm-thick SiON film 7 in bottom-to-top order; and each of grooves 1a is formed between adjacent ones of the multilayer gate electrodes. Each multilayer gate electrode is formed by depositing, on the semiconductor substrate 1, the polysilicon film 2, the titanium nitride film 3, the tungsten film 4, the titanium nitride film 5, the silicon nitride film 6, and the SiON film 7 in bottom-to-top order and then carrying out resist patterning and dry etching. The resist patterning and dry etching are not linked with the feature of the present invention. Thus, a description thereof is not given.

In order to prevent the tungsten film 4 constituting part of each multilayer gate electrode from being oxidized, an approximately 20-nm-thick anti-oxidation film 8 is formed with grooves 1b on the semiconductor substrate 1 and along the sidewalls and bottoms of the grooves 1a and the top surfaces of the multilayer gate electrodes. In this relation, since the PMD film 10A is formed by Low Pressure Chemical Vapor Deposition (LP-CVD) as described later, the anti-oxidation film 8 is formed to prevent the tungsten film 4 constituting part of each multilayer gate electrode from being oxidized due to oxidation during this LP-CVD. Thus, the anti-oxidation film 8 can be formed at a temperature of 400° C. or less and is formed as a film with excellent coverage.

A 40-nm-thick silicon nitride film 9 is formed, as a spacer film for Self-Align Contact (SAC), on the anti-oxidation film 8 and along the sidewalls and bottoms of the grooves 1b. The reason why the silicon nitride film 9 is formed as a spacer film for SAC is that in recent years, SAC structures have come to be used with the advancement of technology nodes.

The PMD film 10A made of a BPSG film is formed, as an interlayer dielectric, on the silicon nitride film 9 by LP-CVD to fill the grooves 1c.

For the TEG for evaluation having the above-described structure, the dimension (depth) to which the PMD 10A fills the grooves 1c is approximately 70 nm, and the width of each groove 1c is approximately 60 nm. After the formation of the PMD 10A, annealing is performed in a nitrogen, oxygen or hydrogen atmosphere to enhance the filling property of the PMD 10A. Furthermore, before observations of the section of the TEG shown in the SEM photograph of FIG. 2, 10-second wet etching is performed as a process intended to recognize the generation of voids, for example, by a buffered hydrofluoric acid (BHF) solution (HF:NH₄F=1:10). A metal interconnect layer is usually formed on the PMD 10A.

As apparent from the comparison between FIGS. 2 and 3, it is seen that the PMD 10A made of a BPSG film according to the embodiment of the present invention has a more excellent property of filling the grooves 1c than the known PMD 10B. As clear from FIG. 3, a void 11 is formed in the known PMD 10B.

In order to clarify the feature of the PMD 10A made of a BPSG film according to the embodiment of the present invention, the impurity concentration profile of the PMD 10A in the depth direction was evaluated.

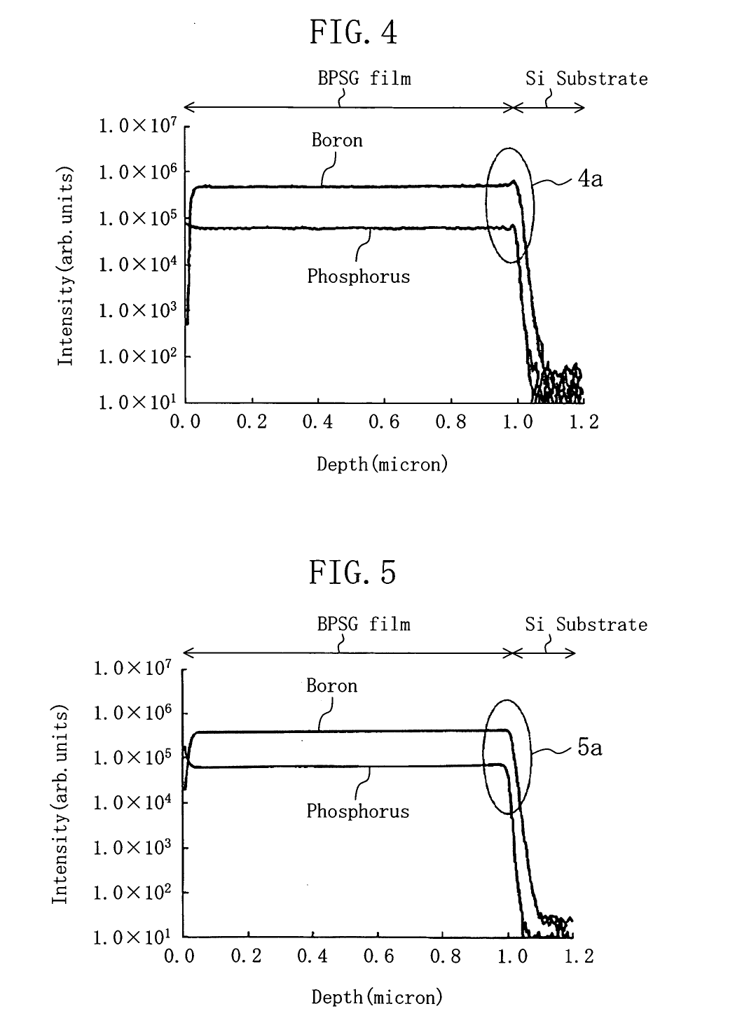

FIG. 4 is a graph showing the SIMS (Secondary Ion Mass Spectroscopy) evaluation results of the boron and phosphorus concentration profiles during the formation of the PMD 10A according to the embodiment of the present invention. FIG. 5 is a graph showing the SIMS evaluation results of the boron and phosphorus concentration profiles during the formation of the known PMD 10B, for comparison with the embodiment of the present invention.

As clear from FIGS. 4 and 5, the total amount of impurities in the PMD 10A according to the embodiment of the present invention during the formation of the PMD 10A is hardly different from that in the known PMD 10B during the formation of the known PMD 10B. Thus, it is no exaggeration to say that they are identical with each other. The result of measuring the impurity amounts of boron and phosphorus by Fourier Transform Infrared Spectroscopy (FT-IR) analysis before SIMS evaluation also showed no significant difference between the PMD 10A according to the embodiment of the present invention and the known PMD 10B. More particularly, the concentrations of boron and phosphorus were 4.5 wt % and 6.0 wt %, respectively, in both the PMD 10A according to the embodiment of the present invention and the known PMD 10B when evaluated by FT-IR.

However, as apparent from FIGS. 4 and 5, the PMD 10A of a BPSG film with an excellent filling property according to the embodiment of the present invention has shown a significant feature in boron and phosphorus concentration profiles. More particularly, the concentrations of boron and phosphorus in the PMD 10A according to the embodiment of the present invention are not uniform in the depth direction as shown in FIG. 4. Furthermore, a part of the PMD 10A formed in the early stages of the formation thereof (a part thereof equivalent to a region of the PMD 10A located in the vicinity of the semiconductor substrate 1 (bulk)) has higher boron and phosphorus concentrations than a region of the PMD 10A located in the vicinity of the top surface thereof and a middle region of the PMD 10A (see 4a in FIG. 4). To be specific, the concentrations of boron and phosphorus in the region of the PMD 10A located in the vicinity of the semiconductor substrate 1 are 10% through 20% both inclusive higher than the average impurity concentration in the PMD 10A.

As described above, the feature of the PMD 10A according to the embodiment of the present invention is that the region of the PMD 10A located in the vicinity of the semiconductor substrate 1 has a impurity concentration profile in which it has a higher impurity concentration than the region of the PMD 10A located in the vicinity of the top surface thereof and the middle region thereof. When the region of the PMD 10A located in the vicinity of the semiconductor substrate 1 thus has high boron and phosphorus concentrations, this means that a large amount of unreacted material gases are produced during the formation of the PMD 10A and thus the fluidity of the PMD 10A is not lost during the formation thereof (a method for forming the PMD 10A will be described later). Since a sufficient fluidity is therefore ensured during both the formation of the PMD 10A and the subsequent annealing, this allows the PMD 10A to have an excellent property in which the grooves 1c are filled. On the other hand, a part of the known PMD 10B formed in the early stages of the formation of the PMD 10B does not exhibit the same feature as the PMD 10A (see 5a in FIG. 5). Since the fluidity of the PMD 10A is not lost, this allows the PMD 10A to have excellent flatness. Therefore, the processing time of Chemical Mechanical Polishing (CMP) after the formation of the PMD 10A can be shortened, and the productivity of a CMP apparatus can be improved. The CMP is intended to reduce the global level difference.

Next, a description will be given of a semiconductor device fabricating method according to the embodiment of the present invention, and a semiconductor device fabricating apparatus used for the method, i.e., a semiconductor device fabricating apparatus used for the formation of the PMD 10A according to the embodiment of the present invention.

FIG. 6 is a cross-sectional view showing the structure of the principal part of the semiconductor fabricating apparatus according to the embodiment of the present invention. More specifically, it is a cross-sectional view showing the structure of the principal part of a CVD apparatus for carrying out the semiconductor device fabricating method shown in FIG. 1.

As shown in FIG. 6, a chamber 102 holding a wafer (semiconductor substrate) 101 on which a PMD 10A is formed is provided with a susceptor 103 having a mechanism for heating the wafer 101. If any of a resistance heating system in which a heater is mounted in the susceptor 103 and a lamp heating system in which the susceptor 103 or the wafer 101 is directly heated by a lamp is used as a system for heating the wafer 101, this does not affect the formation of the PMD 10A according to the embodiment of the present invention.

The wafer 101 is mounted in the chamber 102, and thereafter the wafer 101 is heated on the susceptor 103 to have a desired temperature. In this case, the chamber 102 may be in any of a vacuum and an atmosphere during the heating of the wafer 101. However, since the PMD 10A is formed under a subatmospheric pressure range of 1.33×10⁴ through 7.98×10⁴ Pa (100 through 600 Torr), the wafer 101 is preferably heated under the pressure range within which the PMD 10A is formed. The temperature at which the wafer 101 is heated is preferably 400° C. or more. The PMD 10A shown in FIGS. 1 and 2 according to this embodiment is formed at a temperature of 450° C. under a pressure of 2.66×10⁴ Pa (200 Torr).

Since the PMD 10A is formed under the subatmospheric pressure range, a throttle valve 104, a main valve 105 and a vacuum pump 106 all for performing pressure control are provided for the chamber 102. They are joined together by a vacuum pipe. The throttle valve 104 is for performing pressure control during the formation of the PMD 10A. Throttle valves include valves having a wide variety of systems. A valve having any system may be used as the throttle valve 104.

The chamber 102 is provided with a shower head 107 for supplying material gases onto the wafer 101 with uniformity. The shower head 107 is mounted with a material gas pipe 108 through which material gases are supplied. Valves 109 for stopping the supplies of the material gases, respectively, are provided upstream of the material gas pipe 108. Furthermore, mass flow controllers 110 (flow rate controllers) for controlling the flow rates of the material gases, respectively, are provided upstream from the corresponding valves 109. Other Valves 109 for stopping the supplies of the material gases, respectively, are also provided in the immediate right vicinity of the mass flow controllers 110 when viewed from the front of the sheet of FIG. 6. Although the valves 109 are not directly relevant to the feature of the present invention, they are utilized as emergency shut-off valves to reduce particles produced by the material gases, stabilize the supply of the material gases and serve as one of security measures.

FIG. 6 shows only three material-supplying mass flow controllers 110 for three kinds of material gases. The number of mass flow controllers 110 may be increased depending on the types of necessary material gases. In the embodiment of the present invention, the controllability and responsiveness of the mass flow controllers 110 become significant. Therefore, a logging system (data logger) 111 (monitoring mechanism) for monitoring the actual flows of the material gases, a control signal and a signal indicating the opening/closing of the valves 109 is provided for the mass flow controllers 110. Since the statuses of each of wafers are thus under control, abnormal film formation can be sensed early so that the abnormally formed one of the wafers can be sorted out, and the abnormality of a semiconductor device fabricating apparatus can be detected early. A residual gas analyzer (RGA) 112 (monitoring mechanism) for monitoring the partial pressure of a gas in the chamber 102 is provided for the chamber 102 with the same aim as that with which the logging system 111 is provided. This permits the control of an atmosphere in the chamber 102 in the early stages of the film formation. Control information for the atmosphere can be fed back to the mass flow controllers 110, thereby making an adjustment to increase the impurity concentrations in a region of the PMD 10A located in the vicinity of the semiconductor substrate 1.

The CVD apparatus also has a mechanism which stops the supplies of the material gases or the like and further a film formation process. This mechanism acts when desired impurity concentration profiles for a PMD predetermined to give the PMD desired impurity concentrations during its formation do not correspond with the status of the actual flows of the material gases or the change of a gas atmosphere in the chamber 102, which have both been monitored by the monitoring mechanisms (the logging system 111 and the RGA 112). More particularly, when it is judged by the mass flow controllers 110 that the above-described impurity concentration profiles do not correspond with the status of the actual flows of the material gases or the change of the gas atmosphere, the valves 109 are closed so that the flow rates of the material gases become zero. Thus, a film formation process stops.

Since the above-mentioned logging system 111 and RGA 112 are provided for the purpose of controlling the impurity concentrations in the region of the PMD 10A located in the vicinity of the semiconductor substrate 1, they are components required to control the impurity concentrations in the region of the PMD 10A located in the vicinity of the semiconductor substrate 1. However, when the mass flow controllers 110 each have high performance, very excellent response time to a film formation program and very excellent controllability, the monitoring mechanisms, i.e., the logging system 111 and the RGA 112, need not always be provided. Nevertheless, if in the future the wafer diameter increases and wafer-to-wafer control is needed, the monitoring mechanisms, i.e., the logging system 111 and the RGA 112, will be required.

Next, a description will be given of a method for forming a PMD 10A according to the embodiment of the present invention with the aim of increasing the impurity concentrations in a region of the PMD 10A located in the vicinity of a semiconductor substrate 1.

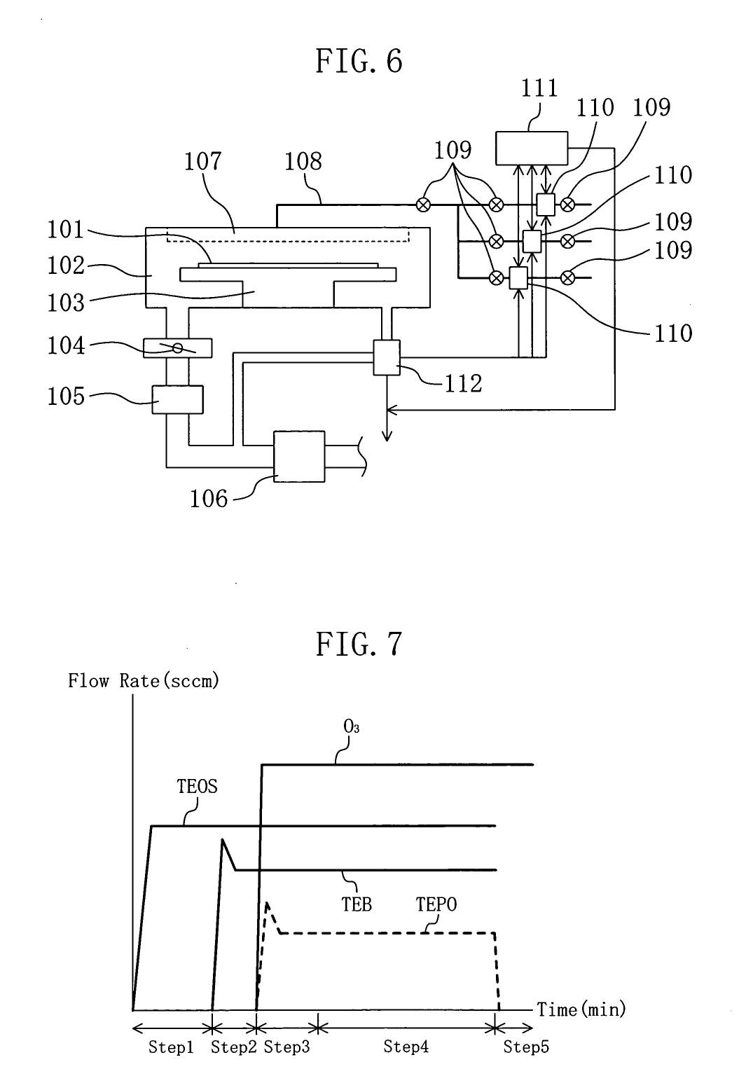

FIG. 7 is a schematic graph showing the flows of material gases for forming the PMD 10A according to the embodiment of the present invention. In FIG. 7, an axis of abscissas represents the time, and an axis of ordinates represents the flow rate of each of material gases.

First, in the first step (step 1), a wafer 101 is placed in a chamber 102, and then the wafer 101 is heated until the temperature thereof reaches a desired temperature. Furthermore, in the first step, a material gas which is under control to have a desired pressure is introduced into the chamber 102. For example, a TEOS gas which is under pressure control to have a pressure of 2.66×10⁴ Pa (200 Torr) is allowed to flow into the chamber 102 at a flow rate of 5×10⁻¹ l/min (500 sccm). When the temperature of the heated wafer 101 reaches a desired temperature, 450° C., this process proceeds to the second step.

Next, in the second step (step 2), a TEB gas is allowed to flow into the chamber 102 at a flow rate of 1.6×10⁻¹ l/min (160 sccm) with the aim of doping a film with boron serving as an impurity. In this relation, the mass flow of the TEB gas is controlled, thereby providing a gas flow causing overshoot immediately after the flow of the TEB gas starts. The purpose for this is to make the concentration of boron in the region of the PMD 10A located in the vicinity of the semiconductor substrate 1 higher than that in a region of the PMD 10A located in the vicinity of the top surface thereof or a middle region thereof. The TEB gas is allowed to flow into the chamber 102 in the second step, and then a TEPO gas and an O³ gas are allowed to flow thereinto only after the third step (step 3) that will be described later. The reason for this is that the TEB gas is allowed to flow into the chamber 102 a little earlier than the timing at which the TEPO gas and the O³ gas are allowed to flow thereinto in view of the following: (a) the fact that the TEB gas is inferior in controllability of mass flow to the other gases; and (b) the fact that the flows of the TEPO gas and the O³ gas in the third step allow boron serving as a dopant to react with the TEPO gas and the TEOS gas, leading to the reduced concentration of boron in the region of the PMD 10A located in the vicinity of the semiconductor substrate 1. More specifically, the time required for the second step is approximately 20 seconds, although it is also determined by the dimensions of the chamber 102, the flow rates of gases to be introduced into the chamber 102 and other factors.

Next, in the third step, the TEPO gas (whose flow rate is approximately. 1×10^{-1 l l/min (}100 sccm)) and the O³ gas serving as an oxidizing agent (whose flow rate is 5 l/min (5000 sccm)) are allowed to flow into the chamber 102. In this relation, for the same purposes as those mentioned above for the TEB gas, the mass flow of the TEPO gas is controlled, thereby providing a gas flow causing overshoot immediately after the flow of the TEPO gas starts. On the other hand, since the O³ gas is an oxidizing agent, its gas flow need not be overshot unlike the TEPO gas. Next, in the fourth step (step 4), the time required for the fourth step is adjusted to provide a desired film thickness, thereby maintaining the gas flow rates stabilized in the third step.

Finally, in the fifth step (step 5), the TEB gas, the TEOS gas and the TEPO gas are removed from the inside of the chamber 102 such that the wafer 101 can be taken out of the chamber 102. In the above description, representative numerical values were used as the flow rates of the TEB gas, the TEOS gas, the TEPO gas and the O³ gas, because the above flow rates need be controlled to provide desired concentrations of boron and phosphorus in the PMD 10A. Desired concentrations of impurities, i.e., boron and phosphorus, in the PMD 10A according to the embodiment of the present invention are 4.0 wt % and 6.0 wt %, respectively. In this case, in order to realize the impurity concentration profiles shown in FIG. 4, the supply of the TEG gas and the TEPO gas need be allowed to overshoot during the formation of the region of the PMD 10A located in the vicinity of the semiconductor substrate 1. Thus, a large amount of unreacted material gases are produced during the formation of the region of the PMD 10A located in the vicinity of the semiconductor substrate 1, and many unreacted material gases are contained in the PMD 10A. Therefore, the fluidity of the PMD 10A is not lost even during the formation of the PMD 10A. This can provide a PMD 10A having an excellent property in which the grooves 1c are filled. Since the fluidity of the PMD 10A is not lost, this allows the PMD 10A to have excellent flatness. Therefore, the processing time of Chemical Mechanical Polishing (CMP) after the formation of the PMD 10A can be shortened, and the productivity of a CMP apparatus can be improved. The CMP is intended to reduce the global level difference.

When it is evaluated whether or not the region of the PMD 10A located in the vicinity of the semiconductor substrate 1 has desired impurity concentration profiles, this is typically carried out, by a nondestructive inline inspection, on the formed PMD 10A after the execution of all the above-mentioned steps. There has been no other evaluation method. Since the semiconductor device fabricating apparatus according to the embodiment of the present invention comprises the logging system 111 and the RGA 112, the actual flows of the material gases controlled by the mass flow controller 110 are detected by the logging system 111, and the atmosphere in the chamber 102 in which the PMD 10A is formed is analyzed by the RGA 112. Therefore, whether or not the PMD 10A has desired impurity concentration profiles can be evaluated with accuracy. Recent digitalization of mass flow controllers allow information obtained by the mass flow controllers 110 to load directly into a control system. In this case, the logging system 111 need not be provided for this embodiment.

As described above, in order to realize an excellent filling property when the interelement spaces are filled with a PMD made of a BPSG film, it is significant to make the concentrations of impurities in a region of the PMD located in the vicinity of a semiconductor substrate higher than those in a region of the PMD located in the vicinity of the top surface thereof or a middle region thereof.

The semiconductor device according to the present invention and an apparatus for fabricating the same are useful when grooves (recesses) each having a higher aspect ratio with the advancement of miniaturization of semiconductor devices are filled with a dielectric.

1. A semiconductor device comprising:
a plurality of elements formed on a semiconductor substrate; and
an interlayer dielectric formed on the semiconductor substrate to fill spaces between adjacent ones of the plurality of elements,
wherein the concentration of an impurity in the interlayer dielectric is nonuniform in a direction along the thickness of the interlayer dielectric.

2. The semiconductor device of claim 1, wherein
the interlayer dielectric contains at least one of boron and phosphorus as the impurity.

3. The semiconductor device of claim 1, wherein
the impurity concentration in a region of the interlayer dielectric located in the vicinity of the semiconductor substrate is higher than the average impurity concentration in the interlayer dielectric.

4. The semiconductor device of claim 3, wherein
the impurity concentration in the region of the interlayer dielectric located in the vicinity of the semiconductor substrate is 10% through 20% both inclusive higher than the average impurity concentration in the interlayer dielectric.

5. A semiconductor device fabricating apparatus that forms an interlayer dielectric on a semiconductor substrate to fill spaces between a plurality of elements formed on the semiconductor substrate by introducing a plurality of material gases into a chamber,
wherein said apparatus comprises:
flow rate controllers for controlling the flow rates of the plurality of material gases, respectively; and
a monitoring mechanism for monitoring the flow rates of the plurality of material gases or an atmosphere in the chamber during the formation of the interlayer dielectric.

6. The apparatus of claim 5, wherein
the monitoring mechanism for monitoring the atmosphere in the chamber is a residual gas analyzer.

7. The apparatus of claim 5, further comprising
a process stopping mechanism for stopping the formation of the interlayer dielectric when the statuses of the monitored flow rates of the plurality of material gases or the change of the monitored atmosphere in the chamber do not correspond with desired impurity concentration profiles of the interlayer dielectric.
